(19) United States
(12) Patent Application Publication
(10) Pub. No.: US 2021/0227701 A1
(43) Pub. Date: Jul. 22, 2021

(54) DESIGN AND PACKAGING METHOD FOR PCB BOARD TO AVOID PATCH ELEMENT TOMBSTONE AND PCB BOARD

(71) Applicant: ZHENGZHOU YUNHAI INFORMATION TECHNOLOGY CO., LTD., Zhengzhou, Henan (CN)

(72) Inventor: Yingna WANG, Zhengzhou, Henan (CN)

(73) Assignee: ZHENGZHOU YUNHAI INFORMATION TECHNOLOGY CO., LTD., Zhengzhou, Henan (CN)

(21) Appl. No.: 16/097,234

(22) PCT Filed: Nov. 30, 2017
(86) PCT No.: PCT/CN2017/113702

§ 371 Date: Oct. 26, 2018

(30) Foreign Application Priority Data
Jul. 31, 2017 (CN) 201710639229.3

(51) Int. Cl. H05K 3/34; H05K 1/11

(52) U.S. Cl. CPC H05K 3/3426; H05K 1/181; H05K 1/111

(57) ABSTRACT

A design method and a packaging method for a PCB board to avoid patch element tombstone, and a PCB board are provided. The method includes: providing at least one patch element placement area on a PCB board, providing pads in each patch element placement area, where each pad group includes two pads, and the two pads are arranged side by side; establishing pad limit areas around the pads; and reflow soldering the patch element to the PCB board. With the above method, the tombstone phenomenon of the patch element can be effectively prevented, the design efficiency is improved, the workload of manual operation of the engineer is reduced, and an error rate is reduced.

This application claims the priority to Chinese Patent Application No. 201710639229.3 titled “DESIGN AND PACKAGING METHOD FOR PCB BOARD TO AVOID PATCH ELEMENT TOMBSTONE AND PCB BOARD”, filed with the Chinese Patent Office on Jul. 31, 2017, which is incorporated herein by reference in its entirety.

### FIELD

The present disclosure relates to the technical field of PCB board packaging, in particular to a design method and a packaging method for a PCB board to avoid patch element tombstone, and a PCB board.

### BACKGROUND

During the manufacturing stage of server boards in a printed circuit board assembly (PCBA) factory, one end of the patch element such as a resistor or a capacitor stands up in the reflow soldering process of the surface mount process. That is because when the solder paste on the pads is melting, two solder ends of the patch element bear different surface tensions and the end bearing the larger tension pulls the patch element to rotate. This phenomenon is called tombstone phenomenon. There are many factors that cause surface tension imbalance, for instance the low preheating temperature is set or the short preheating temperature is set, the shapes and sizes of the pads at both ends of the patch element are inconsistent, the thickness of the solder paste is thick, the patch element mounting offset and the patch element deviation is large, the volume and weight of the patch element are small. All these factors may cause the tombstone phenomenon.

In order to avoid the occurrence of the tombstone phenomenon, the patent ZL201611147023.0, titled “DESIGN METHOD FOR PADS OF 0201 ELEMENT AND PCB BOARD”, describes the following technical solution. A design method for pads of 0201 element and a PCB board are disclosed. With the method, a right angle chamfer is provided on a square pad of the 0201 element. Each square pad group of the 0201 element includes two pads, and the two square pads are arranged side by side. Each square pad is provided with two chamfers, and two chamfers are arranged on an outer side of the square pad. According to the patent, the layout space can be saved, green oil is prevented coating on the pad, and the PCB yield is improved by modifying the pad design of the 0201 element, thereby preventing tombstone from occurring in a circular pad and improving a process yield of the PCBA. In the patent, the tombstone phenomenon is prevented by changing the pad shape.

Practically, in the PCB design process, the patch elements such as resistors and capacitors usually contain copper wire at one end and copper sheet at the other end, resulting in that the solder paste at the copper sheet end melts slower during the reflow soldering process due to faster heat dissipation, while the solder paste melts faster at the other end and the adhesion force to the element is stronger, the copper sheet end is pulled up to cause a tombstone phenomenon. In order to avoid the tombstone phenomenon, in conventional PCB design, the pad properties of the patch elements such as resistors and capacitors are usually manually set to reduce contact areas between the pads and the copper sheet. For instance, three copper wires are connected to a pad by manually setting to reduce the contact area between the pad and the copper sheet, thereby reducing the heat dissipation rate and avoiding the occurrence of the tombstone phenomenon. However, there are still the following disadvantages: 1. layout engineers have a large workload due to the requirement of manually setting pad properties; 2. it is easy to cause omission and low design efficiency in the design process because of a continuous addition of new resistors, capacitors and other patch elements. Therefore, the tombstone phenomenon reduces the manufacturability of the PCB board.

### SUMMARY

The object of the present disclosure is to provide a design method and a packaging method for a PCB board to avoid patch element tombstone, and a PCB board, so as to solve the problem in the conventional technology that the solder paste melts slower at the copper sheet end than the copper wire end during the reflow soldering process, and the adhesion force to the patch element at the end where the solder paste melts faster is stronger and pulls the other end up to cause a tombstone phenomenon.

The technical effect of the present disclosure is realized in the following manner.

A design method for a PCB board to avoid patch element tombstone is provided, which includes: step a1, providing at least one patch element placement area on a PCB board, and providing pads in each of the at least one patch element placement area, where each pad group includes two pads, and the two pads are arranged side by side; and step a2, establishing pad limiting areas around the pads.

Optionally, step a2 includes: establishing pad limiting areas around all the pads on the PCB board.

Optionally, step a2 includes: establishing pad limiting areas around a part of the pads on the PCB board; and printing the PCB board such that a pad limiting area pattern is printed on the pad limiting area.

A packaging method for a PCB board to avoid patch element tombstone is provided. In which, one end of a patch element is made of copper sheet, the other end of the patch element is made of copper wire, or both ends of the patch element are made of copper sheet. The packaging method includes: obtaining a PCB board by performing step a2 of establishing pad limiting areas around all the pads on the PCB board; and mounting both ends of the patch element on the pad to perform reflow soldering.

A packaging method for a PCB board to avoid patch element tombstone is provided.

In which, one end of a patch element is made of copper sheet, the other end of the patch element is made of copper wire, or both ends of the patch element are made of copper sheet. The packaging method includes: obtaining a PCB board by performing step a2 of establishing pad limiting areas around a part of the pads on the PCB board and printing the PCB board such that a pad limiting area pattern is printed on the pad limiting area, where pad limiting area patterns are printed around a part of the pads on the PCB board; and mounting the copper sheet end of the patch element on the pad which is printed with pad limiting area patterns to perform reflow soldering.

Optionally, the packaging method includes: mounting the copper wire end of the patch element on the pad which is not printed with pad limiting area patterns to perform reflow soldering.

Optionally, the pad limiting area pattern is divided into a left limiting area pattern and a right limiting area pattern, the left limiting area pattern has a symmetric sector shape, and the right limiting area pattern has an arc shape.

Optionally, an isolation region is arranged between two adjacent pad limiting area patterns.

A PCB board is provided, which includes patch element placement areas and pads. The PCB board is provided with at least one patch element placement area, each of the at least one patch element placement area is provided with pads, each pad group includes two pads, the two pads are arranged side by side, and pad limiting areas are arranged around the pads.

Optionally, the pad limiting areas are printed with pad limiting area patterns. The pad limiting area pattern is divided into a left limiting area pattern and a right limiting area pattern, the left limiting area pattern has a symmetric sector shape, and the right limiting area pattern has an arc shape. An isolation region is arranged between two adjacent pad limiting area patterns.

The design method and the packaging method for a PCB board to avoid patch element tombstone, and the PCB board according to the disclosure have the following advantages.

1. One end of the patch element is made of copper sheet, the other end of the patch element is made of copper wire. Pad limiting areas are established around all the pads on the PCB board, and the PCB board is printed such that a pad limiting area pattern is printed on the pad limiting area, to obtain the PCB board. Both ends of the patch element are mounted on the pad to perform reflow soldering. The pad limiting area can prevent the connection between the pad and the copper sheet, and reduce a connection area between the pad and the copper sheet, thereby reducing a heat dissipation rate and effectively preventing the tombstone phenomenon caused by uneven heat dissipation at both ends of the patch element.

2. One end of the patch element is made of copper sheet, the other end of the patch element is made of copper wire. Pad limiting areas are established around a part of the pads on the PCB board, and the PCB board is printed such that a pad limiting area pattern is printed on the pad limiting area, to obtain the PCB board. The copper sheet end of the patch element is mounted on the pads which are printed with pad limiting area patterns to perform reflow soldering, and the copper wire end of the patch element is mounted on the pads which are not printed with pad limiting area patterns to perform reflow soldering. In this way, not only the tombstone phenomenon can be avoided, but also design and manufacture costs are reduced in a case of printing pad limiting area patterns only around the pads which are soldered with the copper sheet ends.

3. An isolation region is arranged between two adjacent pad limiting area patterns, and the isolation region is arranged to isolate and distinguish two adjacent pads.

4. By establishing a pad limiting area around a pad, it is unnecessary to manually set the pad properties as the conventional art to reduce the contact area between the pad and the copper sheet, thereby effectively preventing the tombstone phenomenon of patch elements such as resistors and capacitors, improving the design efficiency of engineers, reducing the workload of manual operation of the engineer, and reducing an error rate.

5. The design according to the disclosure has a simple structure, is easy to manufacture, and is convenient to use. With the design, not only the tombstone phenomenon of patch elements such as resistors and capacitors in the reflow soldering process can be avoided, but also the labor intensity of workers can be reduced, thereby improving the work efficiency, saving resources, and reducing design and manufacture costs. Therefore, the disclosure has a good promotion and application value.

### BRIEF DESCRIPTION OF THE DRAWINGS

The present disclosure will be further described with reference to the drawings hereinafter.

FIG. 1 is a schematic structural view of a pad limiting area.

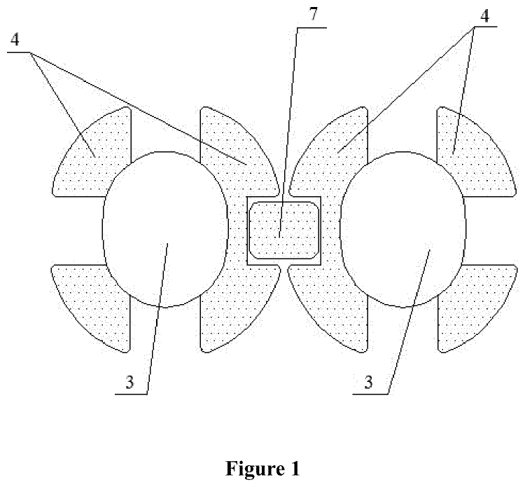

FIG. 2 is a schematic structural view of a PCB board with a pad limiting area.

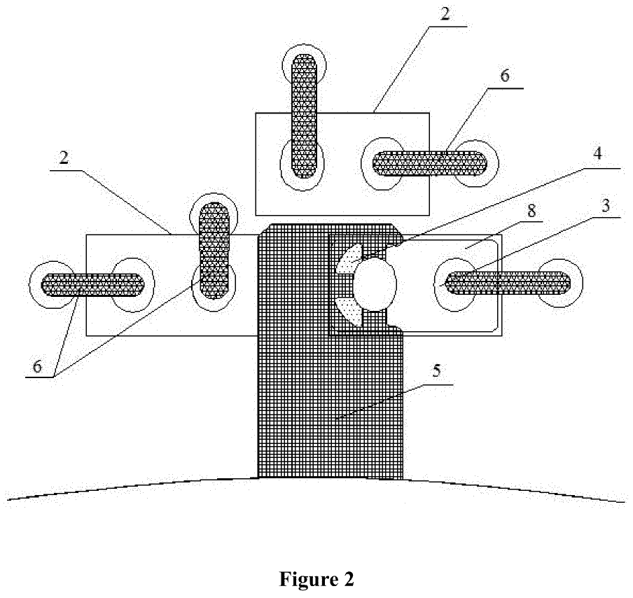

Reference numbers in the drawings are listed as follow:

| | |
|---|---|
| 1 PCB board, | 2 patch element placement area, |
| 3 pad, | 4 pad limiting area, |
| 5 copper sheet, | 6 copper wire, |
| 7 isolation region, | 8 patch element. |

### DETAILED DESCRIPTION OF THE EMBODIMENTS

A design and packaging method for a PCB board to avoid patch element tombstone, and a PCB board according to the disclosure are described in detail hereinafter with reference to the drawings and embodiments.

### First Embodiment

A design method for a PCB board to avoid patch element tombstone of the disclosure includes the following steps.

In step a1, two patch element placement areas 2 are provided on a PCB board, and each patch element placement area 2 is provided with pads 3. Each pad group includes two pads 3, and the two pads 3 are arranged side by side.

In step a2, pad limit areas 4 are established around the pads 3.

Specifically, in step a2, pad limiting areas 4 are established around all the pads 3 on the PCB board 1; and the PCB board 1 is printed such that a pad limiting area pattern is printed on the pad limiting area 4.

### Second Embodiment

A design method for a PCB board to avoid patch element tombstone of the disclosure includes the following steps.

In step a1, three patch element placement areas 2 are provided on a PCB board, and each patch element placement area 2 is provided with pads 3. Each pad group includes two pads 3, and the two pads 3 are arranged side by side.

In step a2, pad limit areas 4 are established around the pads 3.

Specifically, in step a2, pad limiting areas 4 are established around a part of the pads 3 on the PCB board 1; and the PCB board 1 is printed such that a pad limiting area pattern is printed on the pad limiting area 4.

### Third Embodiment

A packaging method for a PCB board to avoid patch element tombstone according to the disclosure is provided. A patch element 8 is a 0402 patch capacitive element, one end of the patch elements 8 is made of copper sheet 5, the other end of the patch element 8 is made of copper wire 6; or both ends of the patch element 8 are made of copper sheet 5. Pad limiting areas 4 are established around all the pads 3 on the PCB board 1. A PCB board 1 is printed such that a pad limiting area pattern is printed on the pad limiting area 4 to obtain the PCB board 1. Both ends of the patch elements 8 are mounted on the pad 3 to perform reflow soldering by solder paste.

### Fourth Embodiment

A packaging method for a PCB board to avoid patch element tombstone according to the disclosure is provided. The patch element 8 is a 0201 patch capacitive element, one end of the patch element 8 is made of copper sheet 5, the other end of the patch element is made of copper wire 6; or both ends of the patch element 8 are made of copper sheet 5. Pad limiting areas 4 are established around a part of the pads 3 on the PCB board 1. The PCB board 1 is printed such that a pad limiting area pattern is printed on the pad limiting area 4 to obtain the PCB board 1. The copper sheet 5 end of the patch element 8 is mounted on the pads 3 which are printed with pad limiting area patterns to perform reflow soldering by solder paste.

### Fifth Embodiment

A packaging method for a PCB board to avoid patch element tombstone according to the disclosure is provided. The patch element 8 is a 0402 patch capacitive element, one end of the patch element 8 is made of copper sheet 5, and the other end of the patch element 8 is made of copper wire 6. Pad limiting areas 4 are established around a part of the pads 3 on the PCB board 1. The PCB board 1 is printed such that a pad limiting area pattern is printed on the pad limiting area 4, to obtain the PCB board 1. The pad limiting area pattern is divided into a left limiting area pattern and a right limiting area pattern, the left limiting area pattern has a symmetric sector shape, and the right limiting area pattern has an arch shape. The copper sheet 5 end of the patch element 8 is mounted on the pads 3 which are printed with pad limiting area patterns to perform reflow soldering by solder paste. The copper wire 6 end of the patch element 8 is mounted on the pads 3 which are not printed with pad limiting area patterns to perform reflow soldering by solder paste. An isolation region 7 is arranged between two adjacent pad limiting area patterns.

### Sixth Embodiment

A PCB board according to the disclosure includes patch element placement areas 2 and pads 3. The PCB board 1 is provided with at least one patch element placement area 2, each patch element placement area 2 is provided with pads 3, each pad group includes two pads 3, and the two pads 3 are arranged side by side. Pad limiting areas 4 are established around the pads 3. The PCB board is printed, such that the pad limiting areas 4 are printed with pad limiting area patterns. The pad limiting area pattern is divided into a left limiting area pattern and a right limiting area pattern, the left limiting area pattern has a symmetric sector shape, and the right limiting area pattern has an arch shape. An isolation region 7 is arranged between two adjacent pad limiting area patterns.

Through the above specific embodiments, those skilled in the art can easily implement the present disclosure. However, it should be understood that the present disclosure is not limited to the above six specific embodiments. Based on the disclosed embodiments, those skilled in the art can combine different technical features to implement different technical solutions.

In addition to the technical features described in the specification, all other techniques are known to those skilled in the art.

1. A design method for a PCB board to avoid patch element tombstone, comprising:
step a1, providing at least one patch element placement area on a PCB board, and providing pads in each of the at least one patch element placement area, wherein each pad group comprises two pads, and the two pads are arranged side by side; and
step a2, establishing pad limiting areas around the pads.

2. The design method for the PCB board to avoid patch element tombstone according to claim 1, wherein step a2 comprises: establishing pad limiting areas around all the pads on the PCB board.

3. The design method for the PCB board to avoid patch element tombstone according to claim 1, wherein step a2 comprises:
establishing pad limiting areas around a part of the pads on the PCB board; and
printing the PCB board, wherein a pad limiting area pattern is printed on the pad limiting area.

4. A packaging method for a PCB board to avoid patch element tombstone, wherein one end of a patch element is made of copper sheet, the other end of the patch element is made of copper wire, or both ends of the patch element are made of copper sheet, and the method comprises:
obtaining a PCB board by using the design method for the PCB board to avoid patch element tombstone according to claim 2; and
mounting both ends of the patch element on the pad, to perform reflow soldering.

5. A packaging method for a PCB board to avoid patch element tombstone, wherein one end of a patch element is made of copper sheet, the other end of the patch element is made of copper wire, or both ends of the patch element are made of copper sheet, and the method comprises:
providing at least one patch element placement area on a PCB board, and providing pads in each of the at least one patch element placement area, wherein each pad group comprises two pads, and the two pads are arranged side by side;
establishing pad limiting areas around a part of the pads on the PCB board, wherein pad limiting area patterns are printed around the part of the pads on the PCB board; and
mounting the copper sheet end of the patch element on the pad which is printed with pad limiting area patterns, to perform reflow soldering.

6. The packaging method for the PCB board to avoid patch element tombstone according to claim 5, comprising: mounting the copper wire end of the patch element on the pad which is not printed with pad limiting area patterns, to perform reflow soldering.

7. The packaging method for the PCB board to avoid patch element tombstone according to claim 5, wherein the pad limiting area pattern is divided into a left limiting area pattern and a right limiting area pattern, the left limiting area pattern has a symmetric sector shape, and the right limiting area pattern has an arch shape.

8. The packaging method for the PCB board to avoid patch element tombstone according to claim 7, wherein an isolation region is arranged between two adjacent pad limiting area patterns.

9. A PCB board, comprising:
patch element placement areas; and
pads, wherein
the PCB board is provided with at least one patch element placement area, each of the at least one patch element placement area is provided with pads, each pad group comprises two pads, the two pads are arranged side by side, and pad limiting areas are established around the pads.

10. The PCB board according to claim 9, wherein the pad limiting areas are printed with pad limiting area patterns; the pad limiting area pattern is divided into a left limiting area pattern and a right limiting area pattern, the left limiting area pattern has a symmetric sector shape, the right limiting area pattern has an arch shape; and an isolation region is arranged between two adjacent pad limiting area patterns.
